(19) United States
(12) Patent Application Publication
(10) Pub. No.: US 2003/0166335 A1
(43) Pub. Date: Sep. 4, 2003

(54) Method of forming wiring in semiconductor devices

(76) Inventors: Hyung Kyun Kim, Kyungki-Do (KR); Min Yong Lee, Seoul (KR); Kwon Son, Kyungki-Do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/032,687

(22) Filed: Dec. 28, 2001

(30) Foreign Application Priority Data
Nov. 30, 2001 (KR) 2001-75440

(51) Int. Cl. H01L 21/44; H01L 21/3205; H01L 21/336

(52) U.S. Cl. 438/669; 438/595; 438/305

(57) ABSTRACT

The invention relates to a method of forming wiring in a semiconductor device. In order to prevent a lift or a crack generated when nitride films having different physical properties come in contact, the invention uses a nitride film having a similar stress characteristic; a nitride film that can be deposited by a low pressure chemical vapor deposition (LPCVD) method in a single type chamber capable of processing wafers one by one, and a nitride film that can be deposited by a low pressure chemical vapor deposition (LPCVD) method in a batch type chamber capable of processing several sheet of wafers.

### BACKGROUND OF THE INVENTION

1. Field of the Invention

The invention relates generally to a method of forming wiring in a semiconductor device and, more particularly, to a method of forming a gate electrode in a transistor having a hard mask made of a nitride film and a spacer or word lines and bit lines in a memory device.

2. Description of the Prior Art

Generally, as the integration level of semiconductor devices becomes higher, the transfer speed of signals is reduced since the width of a pattern is reduced, resulting in problems in the operating speed of the device. In order to prevent a lowering in the operating speed, depending on reduction in the width of the pattern, the thickness of the pattern must be increased. In this case, however, as integration of the device becomes difficult, the wiring is usually formed to have a structure in which polysilicon and metal are stacked.

However, use of this metal causes defective patterns and contamination of deposition or cleaning apparatus due to the difference in an etch ratio with polysilicon to degrade the throughput of the device. In other words, the photolithographic film must be formed thickly in order to pattern metal and polysilicon. However, various problems occur when the pattern is formed using only a thick photolithographic film in an actual process. As one solution to overcome this problem, there has been proposed a method by which a hard mask is formed on a conductive layer to be used as wiring and the conductive layer is then patterned using a hard mask.

A prior art method using the hard mask as described below by reference to FIGS. 1A-1D.

FIGS. 1A-1D are cross-sectional views of a semiconductor device for describing a method of forming wiring in the device, and show a process of forming a gate electrode in a transistor.

Referring to FIG. 1A, a gate oxide film 2, a polysilicon layer 3, a metal layer 4, and a hard mask layer 5 are sequentially formed on a semiconductor substrate 1. Then, photolithographic film patterns 6 are formed on the hard mask layer 5. The metal layer 4 is made of metal such as aluminum (Al), tungsten (W) and titanium (Ti) or suicide. The hard mask layer 5 is made of a nitride film deposited by a plasma chemical vapor deposition (PECVD) method.

Referring to FIG. 1B, the hard mask layer 5 is patterned by an etch process using the photolithographic film patterns 6 as a mask to form hard masks 5a.

By reference to FIG. 1C, the metal layer 4, the polysilicon layer 3, and the gate oxide film 2 are sequentially patterned by an etch process using the hard masks 5a as a mask to form a gate electrode 4a. Next, an impurity ion is implanted into the semiconductor substrate 1 at both sides of the gate electrode 4a to form a junction region 7.

Referring now to FIG. 1D, a spacer 8 as an insulating film is formed at both sides of the hard mask 5a and the gate electrode 4a. The spacer 8 is made of a nitride film, which is deposited by a low-pressure chemical vapor deposition (LPCVD) method in a batch-type chamber capable of processing several sheets of wafers.

However, as this prior art method uses two types of the nitride films having different stress characteristic, i.e., the nitride film constituting the hard mask 5a and the nitride film constituting the spacer 8, as can be seen a “D” portion in FIG. 1D, a lift (“E” portion) or a crack is generated in the interface due to the difference in the stress between the two nitride films, as shown in FIG. 3. In FIG. 2, a graph B illustrates a stress measurement (about 12E9dyn/cm²) of the nitride film deposited by a low-pressure chemical vapor deposition (LPCVD) method and the graph C illustrates a stress measurement (about −2E9dyn/cm²) of the nitride film deposited by a plasma chemical vapor deposition (PECVD) method.

The lift or crack may contaminate the wafer and the apparatus or may cause contact between the wirings when the device is driven or a leakage current to degrade an electrical characteristic of the device. Further, this phenomenon may significantly affect the throughput of the device since it is severe in an edge of the wafer.

### SUMMARY OF THE INVENTION

The invention is intended to solve this problem and an objective of the invention is to provide a method of forming wiring in a semiconductor device capable of preventing a lift or a crack generated when nitride films having different physical properties come in contact, by using a nitride film having similar stress characteristics.

In order to accomplish this objective, a method of forming wiring in a semiconductor device according to the invention is characterized in that it includes the steps of forming a conductive layer on an insulating film formed on a semiconductor substrate; depositing a nitride film by a low-pressure chemical vapor deposition method to form a hard mask layer on the conductive layer; patterning the hard mask layer and patterning the conductive layer using the patterned hard mask; and depositing a nitride by means of a low-pressure chemical vapor deposition method and then etching a spacer to form a spacer at the sidewall of the patterned conductive layer and the bard mask.

The process of depositing the nitride film for forming the hard mask and the spacer preferably is performed in a single type chamber having a temperature of 600° C. to 800° C. and a pressure of 1 Torr to 500 Torr. Also, the process of depositing the nitride film for forming the spacer preferably is performed in a batch type chamber having a temperature of 600° C. to 800° C. and the pressure of 0.1 Torr to 1 Torr.

The invention employs a nitride film having similar stress characteristics in order to prevent a lift or a crack generated when nitride films having different physical properties come in contact. What “the stress characteristic is similar” means is that the stoichiometry of a film is similar. As this means that the basic physical property of the film is similar, the invention uses this characteristic.

A nitride film having a similar stress characteristic includes a nitride film that can be deposited by a low pressure chemical vapor deposition (LPCVD) method in a single type chamber capable of processing wafers one by one, and a nitride film that can be deposited by a low pressure chemical vapor deposition (LPCVD) method in a batch type chamber capable of processing several sheet of wafers.

### BRIEF DESCRIPTION OF THE DRAWINGS

The aforementioned aspects and other features of the invention will be explained in the following description, taken in conjunction with the accompanying drawings, wherein:

FIGS. 1A-1D are cross-sectional views of a semiconductor device for describing a method of forming a wiring in the device;

FIG. 2 is a graph illustrating a stress characteristic of a nitride film; and

FIG. 3 is a partially expanded view of a portion “D” in FIG. 1D.

### DETAILED DESCRIPTION OF PREFERRED EMBODIMENTS

The invention will be described in detail by way of a preferred embodiment with reference to accompanying drawings, in which like reference numerals are used to identify the same or similar parts.

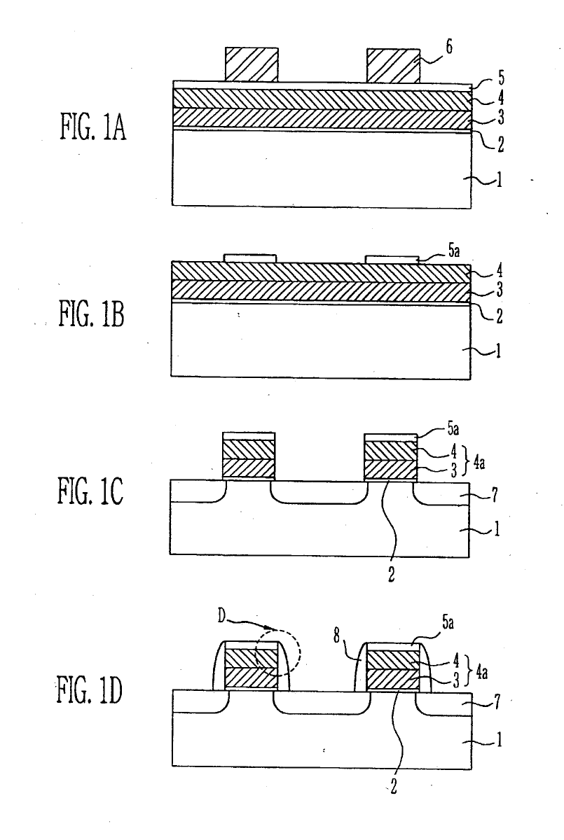

Referring to FIG. 1A, a gate oxide film 2, a polysilicon layer 3, a metal layer 4 and a hard mask layer 5 are sequentially formed on a semiconductor substrate 1. Then, photolithographic film patterns 6 are formed on the hard mask layer 5. The metal layer 4 is made of metal such as aluminum (Al), tungsten (W) and titanium (Ti) or suicide. The hard mask layer 5 uses a nitride film deposited by low-pressure chemical vapor deposition (LPCVD) using SiH₄ and NH₃ in a single type chamber capable of processing a wafer one by one. The deposition process includes the following conditions: the temperature is 600° C. to 800° C. and the pressure is over 1 Torr, preferably, 1 Torr to 500 Torr. Also, the nitride film is formed in a thickness of 500 Å to 3000 Å.

Referring to FIG. 1B, the hard mask layer 5 is patterned by an etch process using the photolithographic film patterns 6 as a mask to form hard masks 5a.

By reference to FIG. 1C, the metal layer 4, the polysilicon layer 3 and the gate oxide film 2 are sequentially patterned by an etch process using the hard masks 5a as a mask to form a gate electrode 4a. Next, an impurity ion is implanted into the semiconductor substrate 1 at both sides of the gate electrode 4a to form a junction region 7.

Referring now to FIG. 1D, a spacer 8 as an insulating film is formed at both sides of the hard mask 5a and the gate electrode 4a. The insulating film for forming the spacer 8 may be formed using a nitride film such as the nitride film used as the hard mask 5a. At this time, the nitride film is formed by a low-pressure chemical vapor deposition (LPCVD) method in a batch type chamber having the pressure of below 1 Torr, preferably 0.1 Torr to 1 Torr. The thickness of the nitride film is 50 Å to 1000 Å.

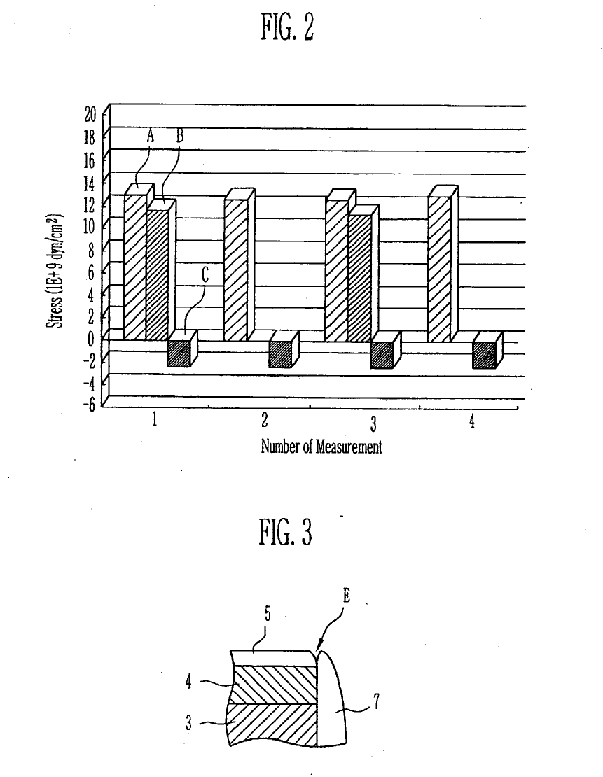

In FIG. 2, a graph A represents a stress measurement (about 13E9dyn/cm²) of the nitride film constituting the hard mask 5a and a graph B is a stress measurement (about 12E9dyn/cm²) of the nitride film constituting the spacer 8. As can be seen from the graphs, as the stress characteristics of two nitride films are similar, there is no any lift or crack at the interface where the two nitride films come in contact, as shown in FIG. 3, if the invention is applied.

Also, through an expensive apparatus is used to deposit the nitride film by means of a plasma chemical vapor deposition (PECVD) method, the invention deposits the nitride film by means of a low-pressure chemical vapor deposition (LPCVD) in a single type chamber capable of processing a wafer one by one. Therefore, the invention can reduce the cost of the process. If the process is performed in a single type chamber, about 54 minutes of time is typically consumed in order to process one wafer. Therefore, the throughput can be improved compared to using a batch type chamber for processing several sheets of wafers.

As mentioned above, the invention employs a nitride film having similar stress characteristics in order to prevent a lift or a crack generated when nitride films having different physical properties come in contact. The nitride film having similar stress characteristics include a nitride film that can be deposited by a low pressure chemical vapor deposition (LPCVD) method in a single type chamber capable of processing wafers one by one, and a nitride film that can be deposited by a low pressure chemical vapor deposition (LPCVD) method in a batch type chamber capable of processing several sheet of wafers.

Therefore, the invention has outstanding advantages that it can improve an electrical characteristic and throughput by preventing contaminated and defective devices due to a lift or a crack generated at the interface where nitride films come in contact. Further, the invention can reduce the manufacturing cost by using a low cost apparatus.

The invention has been described with reference to a particular embodiment in connection with a particular application. Those having ordinary skill in the art and access to the teachings of the invention will recognize additional modifications and applications within the scope thereof.

It is therefore intended by the appended claims to cover any and all such applications, modifications, and embodiments within the scope of the invention.

What is claimed is:

1. A method of forming wiring in a semiconductor device, comprising the steps of:
forming a conductive layer on an insulating film formed on a semiconductor substrate;
depositing a nitride film on said conductive layer by a low-pressure chemical vapor deposition method to form a hard mask layer;
patterning said hard mask layer to form a patterned hard mask;
patterning said conductive layer using the patterned hard mask to form a patterned conductive layer; and
depositing a nitride film by a low-pressure chemical vapor deposition method and then etching a spacer to form a spacer at a sidewall of the patterned conductive layer and the hard mask.

2. The method of claim 1, wherein the process of depositing the nitride film for forming the hard mask and the spacer is performed in a single type chamber having a temperature of 600° C. to 8000° C. and a pressure of 1 Torr to 500 Torr.

3. The method of claim 1, wherein said hard mask is formed in a thickness of 500 Å to 3000 Å.

4. The method of claim 1, wherein the process of depositing the nitride film for forming the spacer is performed in a batch type chamber having a temperature of 600° C. to 800° C. and a pressure of 0.1 Torr to 1 Torr.

5. The method of claim 1, wherein the nitride film for forming the spacer is formed in a thickness of 50 Å to 1000 Å.
